(19) United States
(12) Patent Application Publication
(10) Pub. No.: US 2025/0130383 A1
(43) Pub. Date: Apr. 24, 2025

(54) LIGHT SOURCE UNIT, LIGHT TRANSMISSION MODULE, AND PLUGGABLE OPTICAL MODULE

(71) Applicant: NEC Corporation, Minato-ku, Tokyo (JP)

(72) Inventor: Masayuki NAKANO, Tokyo (JP)

(73) Assignee: NEC Corporation, Minato-ku, Tokyo (JP)

(21) Appl. No.: 18/682,587

(22) PCT Filed: Sep. 29, 2021
(86) PCT No.: PCT/JP2021/035996

§ 371 Date: Feb. 9, 2024

(51) Int. Cl. G02B 6/42; H01S 3/10

(52) U.S. Cl. CPC G02B 6/4278; G02B 6/4266; G02B 6/4286; H01S 3/10015; H01S 3/1003

(57) ABSTRACT

An external resonator outputs a laser light. A heater controls a phase of the laser light. A drive signal output unit outputs a drive signal to the heater. A control unit controls a drive signal provided to the heater by the drive signal output unit. A light monitoring unit monitors intensity of the laser light. The control unit superimposes an applied dither signal having a rectangular wave on the drive signal. The light monitoring unit detects an amplitude of the fluctuation of the laser light caused by the applied dither signal, and outputs a detection result. The control unit monitors the detection result by changing power of the drive signal, searches for the power at which an amplitude of the fluctuation of the laser light becomes a minimum, and determines the searched power as the power of the drive signal.

### TECHNICAL FIELD

The present invention relates to a light source unit, a light transmission module, and a pluggable optical module.

### BACKGROUND ART

On the other hand, for example, in an optical communication system of a standard such as a small form factor pluggable (SFP) or a 10-Gigabit small form factor pluggable (XFP), a pluggable optical module is progressing. The pluggable optical module is an optical transceiver that can be inserted into and removed from a socket of an optical transmission apparatus. In the case of controlling the pluggable optical module, the pluggable optical module receives control information from the optical transmission apparatus on the host side. Then, the operation of the pluggable optical module is switched or changed according to the received control information.

An optical module (optical transceiver) including a pluggable optical module is provided with a light transmission module that transmits an optical signal, and the light transmission module is provided with a light source that outputs laser light and a modulator that modulates the laser light into an optical signal (Patent Literatures 1 and 2).

A wavelength-tunable light source is often used as the light source, where in the wavelength-tunable light source, a wavelength and a phase of laser light to be output are controlled when setting or changing the wavelength (channel). For example, in the case of adjusting the phase, a control method of adjusting the phase by monitoring the amplitude of the laser light by the dither signal using a low-frequency dither signal is known (Patent Literatures 1 to 4).

### CITATION LIST

### Patent Literature

Patent Literature 1: Japanese Unexamined Patent Application Publication No. 2019-121691

Patent Literature 2: Japanese Unexamined Patent Application Publication No. 2017-147622

Patent Literature 3: Japanese Unexamined Patent Application Publication No. 2020-134602

Patent Literature 4: Japanese Unexamined Patent Application Publication No. 2011-253964

### SUMMARY OF INVENTION

### Technical Problem

It is known that a sinusoidal signal is generally used as the dither signal (Patent Literatures 2 and 4). However, a relatively complicated circuit is required to generate a periodic analog signal such as a sinusoidal signal (Patent Literature 4).

On the other hand, in an optical transceiver used in a 10 Gb/s (SFP, XFP) standard, dimensions of a package are defined by the standard, and downsizing and reduction in power consumption of components of the optical transceiver are required to implement the necessary functions.

Therefore, it is desired to realize the dither signal advantageous for downsizing the optical transceiver and the phase control of the laser light output from the wavelength-tunable light source by using dither signal.

The present invention has been made in view of the above circumstances, and an object of the present invention is to control a phase of output laser light by using a dither signal of a rectangular wave in a light source unit.

### Solution to Problem

A light source unit according to one aspect of the present invention includes a semiconductor optical amplifier configured to amplify an input light; an external resonator configured to form an optical resonator in which the light travels back and forth together with the semiconductor optical amplifier, includes a wavelength-tunable filter that can tune a wavelength of a transmitted light, and configured to output a laser light oscillated by the optical resonator and transmitted through the wavelength-tunable filter; a heater provided in an optical waveguide of the external resonator through which the laser light is propagated and configured to control a phase of the laser light; a drive signal output unit configured to output a drive signal to the heater; a control unit configured to control the drive signal to be provided to the heater by the drive signal output unit; and a light monitoring unit configured to monitor intensity of the laser light, in which the control unit controls the drive signal output unit such that a dither signal having a periodic rectangular wave is superimposed on the drive signal, the light monitoring unit detects an amplitude of a fluctuation in intensity of the laser light caused by the dither signal and outputs a detection result to the control unit, and the control unit monitors the detection result from the light monitoring unit while controlling the drive signal output unit so that power of the drive signal changes, and searches for the power at which the amplitude of the fluctuation in the intensity of the laser light becomes a minimum, and determines the searched minimum power as the power of the drive signal.

A light transmission module according to one aspect of the present invention includes a light source unit configured to output a laser light; and a light modulation unit configured to modulate the laser light according to a data signal, and outputs an optical signal; in which the light source unit includes a semiconductor optical amplifier configured to amplify an input light, an external resonator configured to form an optical resonator in which the light travels back and forth together with the semiconductor optical amplifier, includes a wavelength-tunable filter that can tune a wavelength of a transmitted light is variable, and configured to output a laser light oscillated by the optical resonator and transmitted through the wavelength-tunable filter, a heater provided in an optical waveguide of the external resonator through which the laser light is propagated and configured to control a phase of the laser light, a drive signal output unit configured to output a drive signal to the heater, a control unit configured to control the drive signal to be provided to the heater by the drive signal output unit, and a light monitoring unit configured to monitor intensity of the laser light, the control unit controls the drive signal output unit such that a dither signal having a periodic rectangular wave is superimposed on the drive signal, the light monitoring unit detects an amplitude of a fluctuation in intensity of the laser light caused by the dither signal and outputs a detection result to the control unit, and the control unit monitors the detection result from the light monitoring unit while controlling the drive signal output unit so that power of the drive signal changes, and searches for the power at which the amplitude of the fluctuation in the intensity of the laser light becomes a minimum, and determines the searched minimum power as the power of the drive signal.

A pluggable optical module according to one aspect of the present invention includes a pluggable electrical connector configured to be insertable into and removable from an optical transmission apparatus and enabling bidirectional communication with the optical transmission apparatus; a light transmission module configured to an optical signal based on a data signal input from the optical transmission apparatus via the pluggable electrical connector; a light reception module configured to demodulate an input optical signal and outputs the demodulated signal to the optical transmission apparatus; and a pluggable optical receptor configured to allow insertion and removal of an optical fiber, the pluggable optical receptor outputting the optical signal input from the light transmission module to the optical fiber, and outputting the input optical signal input from the optical fiber to the light reception module, in which the light transmission module includes a light source unit that outputs laser light, and a light modulation unit that modulates the laser light according to the data signal and outputs an optical signal, the light source unit includes a semiconductor optical amplifier configured to amplify an input light, an external resonator configured to form an optical resonator in which the light travels back and forth together with the semiconductor optical amplifier, includes a wavelength-tunable filter that can tune a wavelength of a transmitted light is variable, and outputs the laser light oscillated by the optical resonator and transmitted through the wavelength-tunable filter, a heater provided in an optical waveguide of the external resonator through which the laser light is propagated and configured to control a phase of the laser light, a drive signal output unit configured to output a drive signal to the heater; a control unit configured to control the drive signal to be provided to the heater by the drive signal output unit, and a light monitoring unit configured to monitor intensity of the laser light, the control unit controls the drive signal output unit such that a dither signal having a periodic rectangular wave is superimposed on the drive signal, the light monitoring unit detects an amplitude of a fluctuation in intensity of the laser light caused by the dither signal and outputs a detection result to the control unit, and the control unit monitors the detection result from the light monitoring unit while controlling the drive signal output unit so that power of the drive signal changes, and searches for the power at which the amplitude of the fluctuation in the intensity of the laser light becomes a minimum, and determines the searched minimum power as the power of the drive signal.

### Advantageous Effects of Invention

According to the present invention, in the light source unit, the phase of the output laser light by using the dither signal of the rectangular wave can be controlled.

### BRIEF DESCRIPTION OF DRAWINGS

FIG. 1 is a diagram schematically illustrating a configuration of a pluggable optical module according to a first example embodiment.

FIG. 2 is a diagram schematically illustrating a configuration example of a light transmission module according to the first example embodiment.

FIG. 3 is a diagram schematically illustrating a configuration of a light source unit according to the first example embodiment.

FIG. 4 is a diagram illustrating changes in intensity and wavelength of a monitor light when power supplied to a heater is changed by a drive signal on which a dither signal is superimposed.

### EXAMPLE EMBODIMENT

Hereinafter, example embodiments of the present invention will be described with reference to the drawings. In each drawing, the same elements are denoted by the same reference signs, and redundant description is omitted as necessary.

### First Example Embodiment

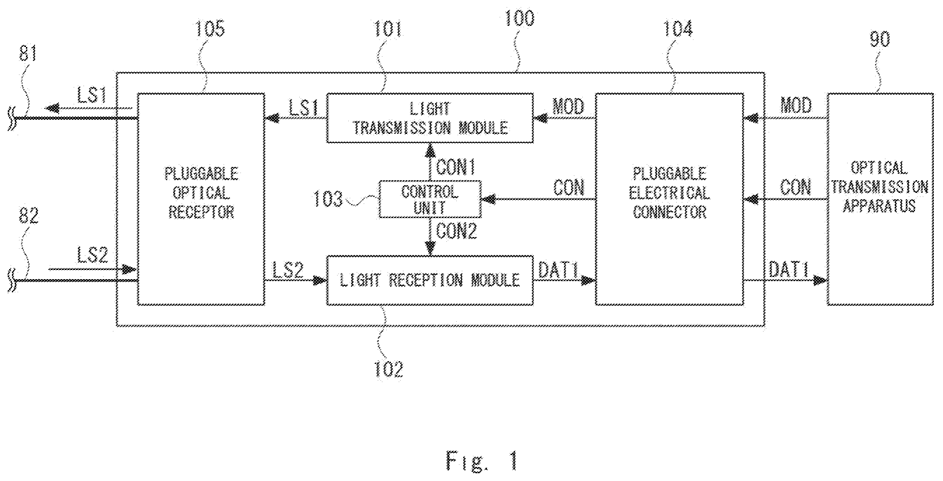

A pluggable optical module 100 according to a first example embodiment will be described. FIG. 1 schematically illustrates a configuration of a pluggable optical module 100 according to the first example embodiment. The pluggable optical module 100 is controlled based on a control signal CON input from an optical transmission apparatus 90 serving as a communication host. The pluggable optical module 100 can receive a modulation signal MOD, which is a data signal, from the optical transmission apparatus 90 together with the control signal CON, and output the optical signal LS1 modulated based on the modulation signal MOD to an optical fiber 81. In addition, the pluggable optical module 100 can receive the optical signal LS2 input from the optical fiber 82 and output a data signal DAT obtained by demodulating the optical signal LS2 to the optical transmission apparatus 90. The optical transmission apparatus 90 performs, for example, communication data processing such as frame processing of a communication data signal from the pluggable optical module 100 or a communication data signal input to the pluggable optical module 100.

The pluggable optical module 100 includes a light transmission module 101, a light reception module 102, a control unit 103, a pluggable electrical connector 104, and a pluggable optical receptor 105.

The pluggable electrical connector 104 is configured to be insertable into and removable from the optical transmission apparatus 90. The pluggable electrical connector 104 receives the control signal CON, which is an electrical signal output from the optical transmission apparatus 90, and transfers the control signal CON to the control unit 103. In addition, the pluggable electrical connector 104 receives the modulation signal MOD, which is an electrical signal output from the optical transmission apparatus 90, and transfers the modulation signal MOD to the light transmission module 101. The pluggable electrical connector 104 may transfer an electrical signal output from the control unit 103 to the optical transmission apparatus 90.

The pluggable optical receptor 105 is configured such that a connector portion of an optical fiber 81 with a transmission connector and a connector of an optical fiber 82 with a reception connector can be inserted and removed. As a connector of the optical fibers 82 and 82 with a connector, for example, an LC type connector or an MU type connector can be used. The pluggable optical receptor 105 sends the optical signal LS1 output from the light transmission module 101 to the optical fiber 81, and sends the optical signal LS2 input from the optical fiber 82 to the light reception module 102.

The control unit 103 controls the operation of the light transmission module 101 by a control signal CON1 and controls the operation of the light reception module 102 by a control signal CON2 based on the control signal CON input from the optical transmission apparatus 90 via the pluggable electrical connector 104.

The light reception module 102 demodulates the optical signal LS2 received via the pluggable optical receptor 105 into the data signal DAT that is an electrical signal, and outputs the data signal DAT to the optical transmission apparatus 90 via the pluggable electrical connector 104. The light reception module 102 is configured to be able to demodulate the optical signal LS2 modulated by various modulation schemes.

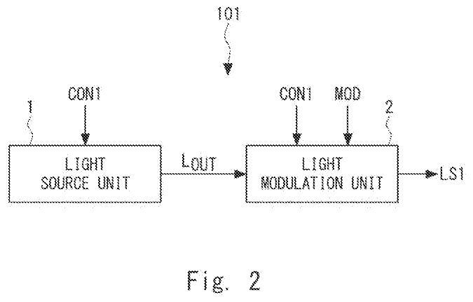

The light transmission module 101 modulates the laser light output from the light source according to the modulation signal MOD, and outputs an optical signal LS1. Next, a configuration example of the light transmission module 101 will be described. FIG. 2 schematically illustrates a configuration example of the light transmission module 101 according to the first example embodiment. The light transmission module 101 includes a light source unit 1 and a light modulation unit 2.

The light source unit 1 is configured as a wavelength-tunable optical module including a semiconductor optical element and a ring resonator, and outputs a laser light L_{OUT} having a predetermined wavelength to the light modulation unit 2.

The light modulation unit 2 includes, for example, a Mach-Zehnder type optical modulator and a drive circuit that drives the Mach-Zehnder type optical modulator. The light modulation unit 2 modulates the laser light L_{OUT} according to the modulation signal MOD and outputs an optical signal LS1. The light modulation unit 2 can modulate the optical signal LS1 by various modulation schemes such as phase modulation, amplitude modulation, and polarization modulation, or by combining the various modulation schemes.

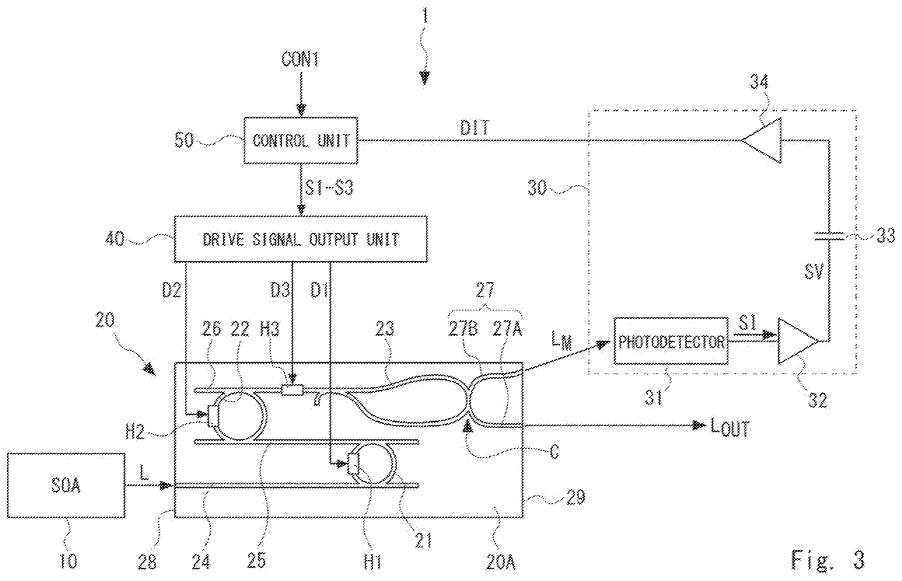

Next, the light source unit 1 will be described. FIG. 3 schematically illustrates a configuration of the light source unit 1 according to the first example embodiment. The light source unit 1 includes a semiconductor optical amplifier (Semiconductor Optical Amplifier, hereinafter referred to as SOA) 10, an external resonator 20, a light monitoring unit 30, a drive signal output unit 40, and a control unit 50.

The SOA 10 is an active optical element that outputs light, and is configured as, for example, a semiconductor laser diode. The SOA 10 is provided with, for example, an optical waveguide having a gain, and outputs laser light from an end face by performing laser oscillation by current injection or the like. Note that in the present example embodiment, the low reflectance coating is applied to an end face 10A on the side of the external resonator 20, and the high reflectance coating is applied to the opposite end face 10B. In addition, the SOA 10 and the external resonator 20 are arranged in a state where the respective waveguides are aligned, and an output light L which is the laser light of the SOA 10 enters the external resonator 20. The output light L has a spectral width of a certain extent, but the wavelength and the phase can be adjusted by the external resonator 20 as described later.

The external resonator 20 resonates the output light L of the SOA 10 to cause laser oscillation, and is configured as a resonator capable of adjusting the wavelength and the phase of the oscillating laser light L_{OUT}. The external resonator 20 is a semiconductor device manufactured by silicon (Si) photonics technology, and is an external resonator having a wavelength-tunable function. The external resonator 20 can be manufactured by a known Si process such as, for example, a complementary metal oxide semiconductor (CMOS) process.

A configuration of the external resonator 20 will be described. In the external resonator 20, ring resonators 21 and 22, a loop mirror 23, silicon optical waveguides 24 to 26, an output optical waveguide 27, and heaters H1 to H3 are formed on a substrate 20A. The ring resonators 21 and 22 are also referred to as first and second ring resonators, respectively. The substrate 20A is configured by, for example, a silicon substrate or a silicon on insulator (SOI) substrate.

The silicon optical waveguides 24 to 26 is configured by a fine wire waveguide or a rib (Rib) waveguide. The silicon optical waveguide 24 optically connects the incident end face 28 and the ring resonator 21. The silicon optical waveguide 25 optically connects the ring resonator 21 and the ring resonator 22. The silicon optical waveguide 26 optically connects the ring resonator 22 and the loop mirror 23. For example, a non-reflective coating (not illustrated) is formed at an end portion of the silicon optical waveguide 24 on the side of the incident end face 28.

The ring resonators 21 and 22 function as filters that can tune the wavelength of transmitted light, and thus, the light resonates between the ring resonators 21 and 22 thus causing laser oscillation. The ring resonators 21 and 22 are provided with heaters H1 and H2, respectively. The silicon optical waveguide forming the ring resonator 21 is heated by the heater H1 to change the optical path length (in other words, the phase of the propagating light), thereby controlling the wavelength of the light reflected by the ring resonator 21. Similarly, the silicon optical waveguide forming the ring resonator 22 is heated by the heater H2 to change the optical path length (in other words, the phase of the propagating light), thereby controlling the wavelength of the light reflected by the ring resonator 22. When the wavelengths of the light reflected by the ring resonators 21 and 22 coincide with each other, the light having the coincided wavelength is laser oscillated.

A heater H3 is provided in the silicon optical waveguide 26 between the loop mirror 23 and the ring resonator 22. When the silicon optical waveguide 26 is heated by the heater H3, the optical path length of the silicon optical waveguide changes, and as a result, the optical path length (resonator length) of the resonator resonator configured between the end face 10B of the SOA 10 and the loop mirror changes. As a result, the phase of the laser light output from the resonator can be controlled.

In this configuration, the phase is adjusted by the heater H3 such that the phase of the laser travelling back and forth in the resonator configured between the end face 10B of the SOA 10 and the loop mirror is in the positive feedback state, so that laser oscillation can be continued and the amplification of the laser light can be maximized. In addition, the laser light having the desired wavelength can be output as the laser light L_{OUT} and a monitor light LM by transmitting only the laser light having the desired wavelength through the loop mirror 23 by the ring resonators 21 and 22.

Note that as described later, the heaters H1 to H3 are controlled by drive signals D1 to D3 output from the drive signal output unit 40, respectively.

The curved portion of the loop mirror 23 is optically connected to the curved portion of the output optical waveguide 27. The two silicon optical waveguides on both sides of the curved portion of the output optical waveguide 27 are extended to the output end face 29, and most of the laser light that entered the loop mirror 23 is coupled to the laser light output waveguide 27A of the output optical waveguide 27 by a coupling portion (coupler C) and is output to, for example, the light modulation unit 2 as the output laser light L_{OUT}. Among the laser light that entered the loop mirror 23, a part of the laser light other than the laser light coupled to the laser light output waveguide 27A is coupled to the monitor light output waveguide 27B by the coupler C, and is output to the light monitoring unit 30 as the monitor light L_{M}.

The light monitoring unit 30 is configured to monitor the intensity of the monitor light L_{M} and output a detection dither signal DIT indicating the monitoring result. The light monitoring unit 30 includes a photodetector 31, a current-voltage converter 32, a capacitor 33, and an amplifier 34.

The photodetector 31 detects the monitor light L_{M} output from the external resonator 20 and outputs a signal indicating the intensity of the detected monitor light L_{M}. The photodetector 31 is configured by, for example, a photodiode, and outputs a detection signal S1 which is a current signal indicating the intensity of the monitor light L_{M}.

The current-voltage converter 32 is configured by, for example, a transimpedance amplifier (TIA), and converts the detection signal S1 which is the current signal to a voltage signal SV and outputs the voltage signal SV.

The voltage signal SV is input to the amplifier 34 via the capacitor 33. The signal in which the DC component is cut from the voltage signal SV by the capacitor 33 is amplified by the amplifier 34, and then output to the control unit 50 as the detection dither signal DIT.

The drive signal output unit 40 outputs drive signals D1 to D3 to the heaters H1 to H3, respectively, according to the control of the control unit 50. Hereinafter, in the present example embodiment, the configuration and operation of the light source unit 1 will be described focusing on the drive signal D3 provided to the heater H3. In the present example embodiment, the drive signal output unit 40 can superimpose an applied dither signal on the drive signal D3 and then output the drive signal D3. Note that in the present example embodiment, for distinction, the dither signal superimposed on the drive signal is referred to as an applied dither signal, and the signal output from light monitoring unit 30 for detecting the intensity amplitude generated in the laser light by the applied dither signal is referred to as a detection dither signal.

The control unit 50 controls the drive signal output unit 40 by a signal S3 such that the drive signal D3 on which the predetermined applied dither signal is superimposed is output to the heater H3. Furthermore, the control unit 50 can also control the drive signals D1 and D2 output to the heaters H1 and H2 by the signals S1 and 2.

The control unit 50 controls heating by the heater H3 in a stepwise manner in order to search for an optimum phase. In the present example embodiment, the control unit 50 periodically changes the current of the drive signal D3 to be provided to the heater H3 within a range that does not affect the wavelength accuracy to obtain the applied dither signal. Specifically, the applied dither signal is provided as a rectangular wave having a predetermined cycle, and the amplitude of the rectangular wave changes in a stepwise manner.

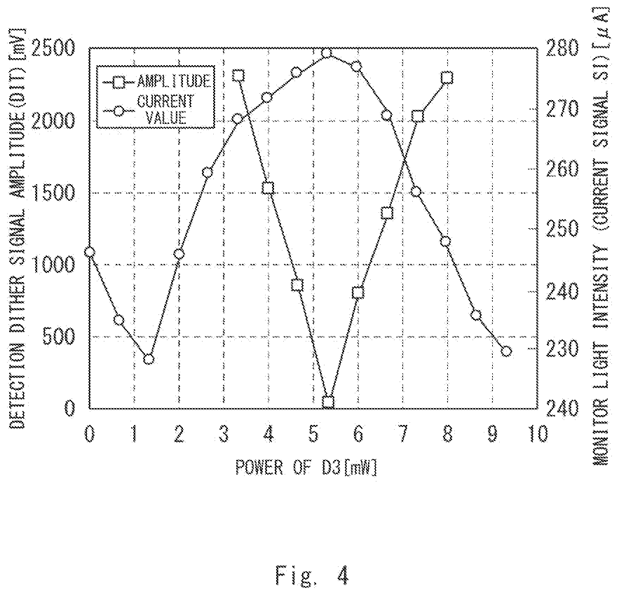

FIG. 4 illustrates changes in intensity and wavelength of the monitor light when the power supplied to the heater H3 is changed by the drive signal D3 on which the applied dither signal is superimposed. In this example, the power supplied to the heater H3 is changed from 0 [mW] to 9+ 4/3 [mW] in units of approximately ⅔ [mW], and accordingly, the change in the amplitude of the detection dither signal DIT output by the light monitoring unit 30 is monitored.

Since the applied dither signal is superimposed on the drive signal D3 provided to the heater H3, the current signal S1 output from the photodetector 31 changes in conjunction with the cycle of the applied dither signal. As a result, amplitude is generated in the detection dither signal DIT. In FIG. 4, in a region where the fluctuation of the current signal with respect to the power change, where the power of the drive signal D3 is approximately 1 to 5 [mW] and 6 to 9 [mW], is large, that is, in a region where the differential value of the current signal is large, the fluctuation of the current signal generated with the change of the applied dither signal superimposed on the drive signal D3 also increases. As a result, the amplitude of the detection dither signal DIT output by the light monitoring unit 30 also increases.

On the other hand, in FIG. 4, in a region where the fluctuation of the current signal with respect to the power change in the vicinity of the vertex of the curve indicating the current in a range where the power of the drive signal D3 is approximately 5 to 6 [mW] is small, that is, in a region where the differential value of the current signal is small, the fluctuation of the current signal generated with the change of the applied dither signal superimposed on the drive signal D3 also decreases. As a result, the amplitude of the detection dither signal DIT output by the light monitoring unit 30 also decreases.

That is, when the power at which the amplitude of the detection dither signal DIT output by the light monitoring unit 30 becomes a minimum is supplied, the phase of the laser light is in an optimum state, that is, the oscillation intensity maximum point of the external resonator 20.

As a result, the control unit 50 can determine the oscillation intensity maximum point of the external resonator 20 by searching for the power value when the amplitude of the detection dither signal DIT becomes a minimum and setting the searched power value to the power of the drive signal D3. In FIG. 4, since the amplitude of the detection dither signal DIT is the minimum when the power of the drive signal D3 is about 5.33 mW, in this case, the power of the drive signal D3 is set to about 5.33 mW. As a result, the phase of the laser light L_{OUT} output from the light source unit 1 can be maintained in an optimum state thereafter.

It is effective to set the drive signal D3 described above when the wavelength of the laser light L_{OUT} is changed in order to set or change the channel of the optical signal to be transmitted. Note that the execution of the setting of the drive signal D3 is not limited to this example, and may be performed when the phase of the laser light L_{OUT} is calibrated after the operation of the pluggable optical module is started, or may be performed at any other timing.

In the present example embodiment, the drive signal output unit 40 may be configured as an analog-digital converter (hereinafter DAC). In the present configuration, the control unit 50 outputs the analog signal on which the applied dither signal component is superimposed to the drive signal output unit 40 as the signal S3. Then, the drive signal output unit 40 converts the signal S3 into a digital signal and outputs the digital signal as the drive signal D3, and the heater H3 is directly driven by the drive signal D3 which is a digital signal.

In addition, in Patent Literatures 1 and 3, a heater is used to control the phase of light in a modulator, but a drive signal is provided to the heater as an analog signal. In this case, a driver (controller in Patent Literature 1 and setting unit in Patent Literature 3) for controlling the current supplied to the heater is provided. However, such a driver has a relatively large circuit scale, which leads to an increase in dimension of the light source unit.

On the other hand, according to the present configuration, the drive signal on which the applied dither signal having a rectangular wave is superimposed can be applied to the heater as a digital signal, to the heater H3, only by providing one DAC between the control unit 50 and the heater H3. This makes it possible to achieve automatic control of the phase of the laser light using the applied dither signal having a rectangular wave, downsizing of the light source unit, and reduction of power consumption.

### Other Example Embodiments

Note that the present invention is not limited to the above example embodiments, and can be appropriately changed without departing from the gist. For example, the configuration of the pluggable optical module (optical transceiver) described above is simplified in order to describe the optical transceiver according to the example embodiment described above, and it goes without saying that other various components may be included.

Although the invention of the present application has been described above with reference to the example embodiments, the invention of the present application is not limited to the above. Various modifications that can be understood by those skilled in the art can be made to the configuration and details of the invention of the present application within the scope of the invention.

### REFERENCE SIGNS LIST

1 LIGHT SOURCE UNIT
2 LIGHT MODULATION UNIT
10 SOA
20 EXTERNAL RESONATOR
20A SUBSTRATE
21, 22 RING RESONATOR
23 LOOP MIRROR
24-26 OPTICAL WAVEGUIDE
27 OUTPUT OPTICAL WAVEGUIDE
27A LASER LIGHT OUTPUT WAVEGUIDE
27B MONITOR LIGHT OUTPUT WAVEGUIDE
28 INCIDENT END FACE
29 OUTPUT END FACE
30 LIGHT MONITORING UNIT
31 PHOTODETECTOR
32 CURRENT-VOLTAGE CONVERTER
33 CAPACITOR
34 AMPLIFIER
40 DRIVE SIGNAL OUTPUT UNIT
50 CONTROL UNIT
81 OPTICAL FIBER
82 OPTICAL FIBER
90 OPTICAL TRANSMISSION APPARATUS
100 PLUGGABLE OPTICAL MODULE
101 LIGHT TRANSMISSION MODULE
102 LIGHT RECEPTION MODULE
103 CONTROL UNIT
104 PLUGGABLE ELECTRICAL CONNECTOR
105 PLUGGABLE OPTICAL RECEPTOR
C COUPLER
CON CONTROL SIGNAL
CON1, CON2 CONTROL SIGNAL
D1-D3 DRIVE SIGNAL
DAT DATA SIGNAL
DIT DETECTION DITHER SIGNAL
H1-H3 HEATER
LS1, LS2
S1-S3 SIGNAL
S1 DETECTION SIGNAL
SV VOLTAGE SIGNAL

What is claimed is:

1. A light source unit comprising:
a semiconductor optical amplifier configured to amplify an input light;
an external resonator configured to form an optical resonator in which the light travels back and forth together with the semiconductor optical amplifier, includes a wavelength-tunable filter that can tune a wavelength of a transmitted light, and configured to output a laser light oscillated by the optical resonator and transmitted through the wavelength-tunable filter;
a heater provided in an optical waveguide of the external resonator through which the laser light is propagated and configured to control a phase of the laser light;
a drive signal output unit configured to output a drive signal to the heater;
a control unit configured to control the drive signal to be provided to the heater by the drive signal output unit; and
a light monitoring unit configured to monitor intensity of the laser light, wherein
the control unit controls the drive signal output unit such that a dither signal having a periodic rectangular wave is superimposed on the drive signal,
the light monitoring unit detects an amplitude of a fluctuation in intensity of the laser light caused by the dither signal and outputs a detection result to the control unit, and
the control unit
monitors the detection result from the light monitoring unit while controlling the drive signal output unit so that power of the drive signal changes, and searches for the power at which the amplitude of the fluctuation in the intensity of the laser light becomes a minimum, and
determines the searched minimum power as the power of the drive signal.

2. The light source unit according to claim 1, wherein the drive signal output unit is configured as an analog-digital converter that converts an analog signal provided from the control unit into a digital signal and outputs the converted digital signal to the heater as the drive signal.

3. The light source unit according to claim 1, wherein the external resonator is configured as a silicon photonics semiconductor device.

4. A light transmission module comprising:
a light source unit configured to output a laser light; and
a light modulation unit configured to modulate the laser light according to a data signal, and outputs an optical signal; wherein
the light source unit includes
a semiconductor optical amplifier configured to amplify an input light,
an external resonator configured to form an optical resonator in which the light travels back and forth together with the semiconductor optical amplifier, includes a wavelength-tunable filter that can tune a wavelength of a transmitted light is variable, and configured to output a laser light oscillated by the optical resonator and transmitted through the wavelength-tunable filter,
a heater provided in an optical waveguide of the external resonator through which the laser light is propagated and configured to control a phase of the laser light,
a drive signal output unit configured to output a drive signal to the heater,
a control unit configured to control the drive signal to be provided to the heater by the drive signal output unit, and
a light monitoring unit configured to monitor intensity of the laser light,
the control unit controls the drive signal output unit such that a dither signal having a periodic rectangular wave is superimposed on the drive signal,
the light monitoring unit detects an amplitude of a fluctuation in intensity of the laser light caused by the dither signal and outputs a detection result to the control unit, and
the control unit
monitors the detection result from the light monitoring unit while controlling the drive signal output unit so that power of the drive signal changes, and searches for the power at which the amplitude of the fluctuation in the intensity of the laser light becomes a minimum, and
determines the searched minimum power as the power of the drive signal.

5. A pluggable optical module comprising:
a pluggable electrical connector configured to be insertable into and removable from an optical transmission apparatus and enabling bidirectional communication with the optical transmission apparatus;
a light transmission module configured to an optical signal based on a data signal input from the optical transmission apparatus via the pluggable electrical connector;
a light reception module configured to demodulate an input optical signal and outputs the demodulated signal to the optical transmission apparatus; and
a pluggable optical receptor configured to allow insertion and removal of an optical fiber, the pluggable optical receptor outputting the optical signal input from the light transmission module to the optical fiber, and outputting the input optical signal input from the optical fiber to the light reception module, wherein
the light transmission module includes
a light source unit that outputs laser light, and
a light modulation unit that modulates the laser light according to the data signal and outputs an optical signal,
the light source unit includes
a semiconductor optical amplifier configured to amplify an input light,
an external resonator configured to form an optical resonator in which the light travels back and forth together with the semiconductor optical amplifier, includes a wavelength-tunable filter that can tune a wavelength of a transmitted light is variable, and outputs the laser light oscillated by the optical resonator and transmitted through the wavelength-tunable filter,
a heater provided in an optical waveguide of the external resonator through which the laser light is propagated and configured to control a phase of the laser light,
a drive signal output unit configured to output a drive signal to the heater;
a control unit configured to control the drive signal to be provided to the heater by the drive signal output unit, and
a light monitoring unit configured to monitor intensity of the laser light,
the control unit controls the drive signal output unit such that a dither signal having a periodic rectangular wave is superimposed on the drive signal,
the light monitoring unit detects an amplitude of a fluctuation in intensity of the laser light caused by the dither signal and outputs a detection result to the control unit, and
the control unit
monitors the detection result from the light monitoring unit while controlling the drive signal output unit so that power of the drive signal changes, and searches for the power at which the amplitude of the fluctuation in the intensity of the laser light becomes a minimum, and
determines the searched minimum power as the power of the drive signal.
